(19) United States
(12) Patent Application Publication
(10) Pub. No.: US 2020/0411317 A1
(43) Pub. Date: Dec. 31, 2020

(54) INTEGRATED CIRCUIT PACKAGE ASSEMBLIES WITH HIGH-ASPECT RATIO METALLIZATION FEATURES

(71) Applicant: Intel Corporation, Santa Clara, CA (US)

(72) Inventors: Jeremy Ecton, Gilbert, AZ (US); Leonel Arana, Phoenix, AZ (US); Brandon Marin, Chandler, AZ (US); Hongxia Feng, Chandler, AZ (US)

(73) Assignee: Intel Corporation, Santa Clara, CA (US)

(21) Appl. No.: 16/453,895

(22) Filed: Jun. 26, 2019

(51) Int. Cl. H01L 21/033; B81C 1/00; B81B 7/00; C25D 7/00; H01L 21/48; H01L 21/768; H01L 21/027; H01L 23/00; G03F 7/095

(52) U.S. Cl. CPC H01L 21/0332; B81C 1/00539; B81B 7/0006; C25D 7/00; H01L 2224/0231; H01L 21/768; H01L 21/0272; H01L 24/02; G03F 7/095; H01L 21/4846

(57) ABSTRACT

Double-patterning methods for build-up metallization features suitable for IC package assemblies. Double-patterned metallization features may, for example, achieve approximately twice the aspect ratio of single patterned metallization features for a given photolithography technology node. High aspect ratio metallization features may include a top feature portion that is over a bottom feature portion. The top and bottom portions each have a distinct sidewall slope indicative of their double-patterning. A hybrid plating mask may be employed during a metallization plating process. The hybrid mask may include multiple layers of photoresist to reach a desired mask thickness. Multiple exposures may be performed to incrementally image the hybrid plating mask, thereby maintaining better resolution for each exposure. In some exemplary embodiments, one layer of the hybrid plating mask has a negative photoresist composition into which features may be hardened through a first exposure, while another layer of the hybrid plating mask has a positive photoresist composition from which features may retained by protecting them from a second exposure.

### BACKGROUND

In electronics manufacturing, integrated circuit (IC) packaging is a stage of semiconductor device fabrication, in which an IC that has been fabricated on a die or chip comprising a semiconducting material is encapsulated in a supporting case or “package” that can protect the IC from physical damage and support electrical contacts that connect the device to a host circuit board. In the IC industry, the process of fabricating a package is often referred to as packaging, or assembly.

IC chips may be assembled in various manners and a number of packaging architectures include a component that comprises metallization features that are built up, for example by electrolytic plating processes. The metallization features may comprise a copper alloy, or another metal that can be readily plated onto a seed layer. A masking of the seed layer may limit such a plating process to form a level of metallization features, such as a conductive vias and traces.

Device packages are now under great pressure to achieve new milestones in form factor even while the complexity of their design increases. Achieving a higher density (i.e. reduce the pitch) of package metallization features generally amounts to increasing the aspect (height: space) of the plating features (or plating mask features).

One option is to improve the resolution of a photolithographic process employed to define a plating mask. Such resolution improvements can come from transitioning to next-generation lithography equipment (e.g., moving from G-line to I-line, from I-line to UV, from UV to DUV, etc.). New materials, such as advanced photoresist formulations, may also be employed in an effort to improve the resolution of plating mask features for a given photolithography exposure wavelength. These options however can add significant costs to a high volume packaging process. Techniques and feature architectures that achieve higher aspect ratios for a given plating mask patterning technology (having some associated equipment and materials) may therefore be advantageous.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods of fabricating a double patterned package metallization feature, in accordance with some embodiments;

FIGS. 2A, 2B, 2C, 2D, 2E, 2F, 2G, 2H, 2I, 2J, 2K, 2L, 2M, 2N, and 2O illustrate cross-sectional views of a package metallization build-up as selected operations in the method illustrated in FIG. 1 are practiced, in accordance with some embodiments;

FIG. 3A illustrates an expanded cross-sectional view of a double-patterned build-up metallization feature, in accordance with some embodiments;

FIG. 3B illustrates cross-sectional view of two adjacent a double-patterned build-up metallization features, in accordance with some embodiments;

FIG. 4 illustrates a cross-sectional view of a package assembly including redistribution level with double-patterned build-up metallization feature, in accordance with some embodiments;

FIG. 5 illustrates a cross-sectional view of a package assembly including a package substrate with a double-patterned build-up metallization feature, in accordance with some embodiments;

FIG. 6 illustrates a mobile computing platform and a data server machine employing a IC package that includes a double-patterned build-up metallization feature, in accordance with some embodiments; and

FIG. 7 is a functional block diagram of an electronic computing device, in accordance with some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Described herein are exemplary double-patterning methods for build-up metallization features suitable for IC package assemblies. Double-patterned metallization features may, for example, achieve approximately twice the aspect ratio of single patterned metallization features for a given photolithography toolset and resist formulation. Many package assemblies include one or more components that have one or more layers of build-up metallization. Build-up metallization is selectively plated into features, such as conductive lines and traces, for carrying electrical current and/or applying electrical voltage to/from one or more IC chip within the package. Build-up metallization generally entails metal features that are selectively plated onto regions where a plating seed is unprotected by an overlying plating mask. Build-up metallization is therefore distinguished from damascene metallization that comprises non-selectively plated features, which have been planarized with surrounding dielectric material so as to be confined within recesses that were previously patterned into the dielectric material. Whereas damascene requires extremely flat substrates relegating the technique to IC chip manufacture, build-up metallization has no such limitation and therefore is favored in package component manufacture whether it may be practiced on reconstituted wafers or other panelized formats, such as those typical in the manufacture of preforms that are enlisted (e.g., as package substrates or interposers) in an IC assembly process.

In some embodiments further described below, a hybrid plating mask is employed during in a metallization plating process. The hybrid mask includes multiple layers of photoresist to reach a desired hybrid mask thickness suitable for plating up a metallization feature of sufficient height. Multiple exposures are performed to incrementally image the hybrid plating mask, thereby maintaining better resolution for each exposure. In some exemplary embodiments, one layer of the hybrid plating mask has a negative photoresist composition into which features may be hardened through a first exposure, while another layer of the hybrid plating mask has a positive photoresist composition from which features may be retained by protecting them from a second exposure. As described further below, the first exposure may employ a photolithographic reticle, while the second exposure may be a flood exposure to expose all portions of the positive photoresist layer unprotected by the overlying photohardened features.

While exposure dosage and/or transmission properties of the negative resist layer may be engineered to ensure the overlying photohardened features sufficiently mask the underlying positive resist layer, in some exemplary embodiments further described below, a hybrid plating mask may further comprise an intervening non-photosensitive layer between the photosensitive layers. The intervening layer may be non-transparent to the optical radiation employed in first and/or second exposure, for example blocking at least a majority of the radiation of the first exposure from interacting with the second photosensitive layer. The intervening layer may be of a hard mask composition that can be selectively etched between the first and second exposures. Selective etch of the intervening layer may be self-aligned to the overlying photohardened mask features. With the non-transmissive material serving as an integrated contact mask, a subsequent imaging of the underlayer is further self-aligned to the upper layer feature, resulting in a high aspect ratio hybrid mask pattern with two perfectly aligned upper and lower mask feature portions. Upon patterning the hybrid plating mask, metallization may be plated according to any suitable technique and the hybrid plating mask then stripped. In addition to achieving higher aspect ratio metallization mask features, embodiments herein may also improve plating mask strip capability as a thick resist strip process may be segmented across multiple discrete resist strip operations.

In some exemplary embodiments, double-patterned metallization features include a top feature portion that is over a bottom feature portion. The top feature portion may have a first aspect ratio while the bottom feature portion has a second aspect ratio. Although the aspect ratios may vary between the top and bottom portions, in some embodiments the two aspect ratios may be substantially equal such that the two portions each have approximately half the aspect ratio of the entire feature. For example, each portion may be of substantially the same average lateral dimension (e.g., transverse width), but have only half the total height of the feature. In some further embodiments, the top and bottom portions each have a distinct sidewall slope indicative of their double-patterning. For example, the top portion may have a first (e.g., positive) sidewall slope while the bottom portion may have a second (e.g., negative) sidewall slope. This characteristic may advantageously enable a space between two adjacent metallization features to achieve some minimum associated with a combination of the complementary sidewall slopes. Hence, not only may the resolution be improved for patterning of both the bottom and top portions of the plated metallization feature, complementary sidewall slopes of the top and bottom portions may reduce differences in critical dimension between the top and bottom of the metallization feature such that adjacent features are less susceptible to shorting at a given feature pitch. As described further below, the increase in aspect ratio achieved in embodiments herein need not entail any loss of alignment and/or overlay margin. In some exemplary embodiments, double-patterned build-up metallization features comprise a bottom feature portion that is exactly aligned with a top feature portion such that a centerline of the top feature portion is coincident with a centerline of the bottom feature portion.

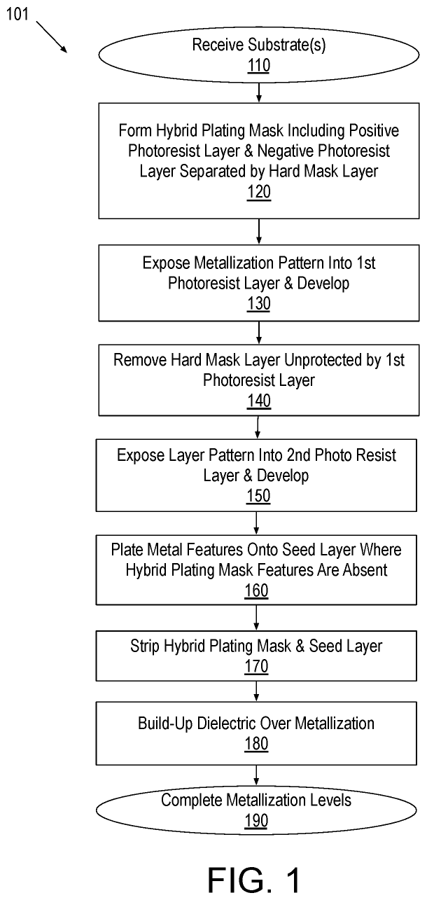

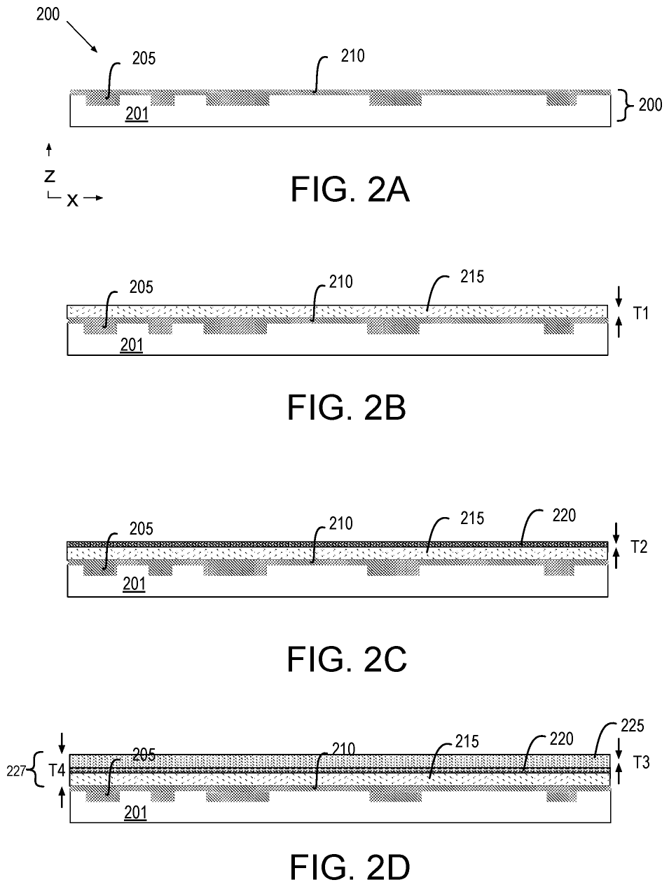

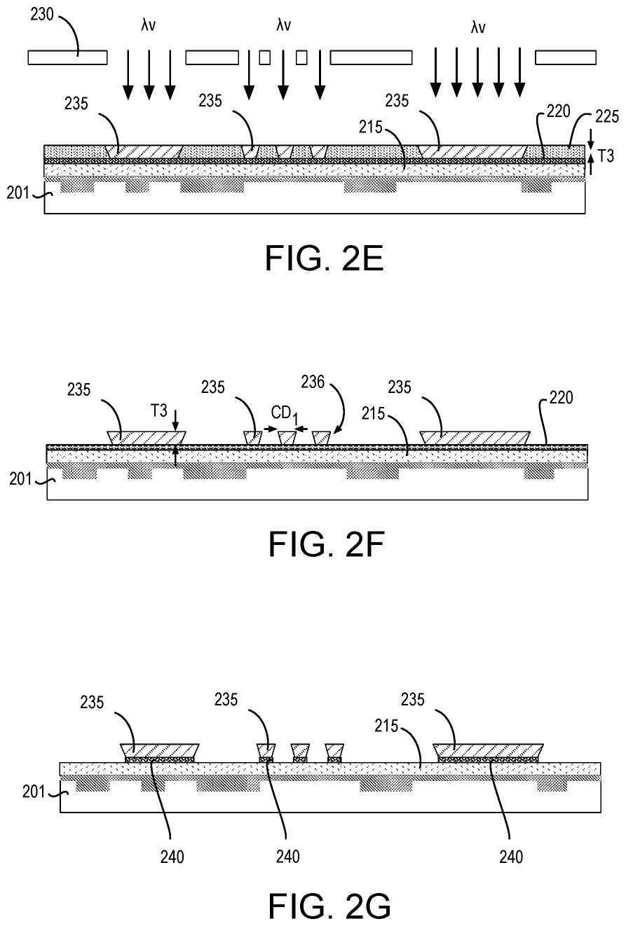

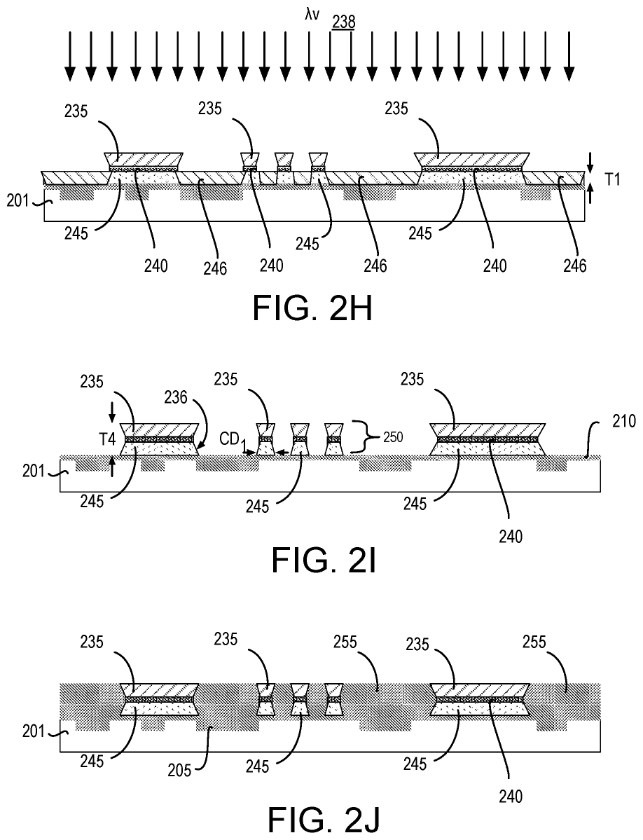

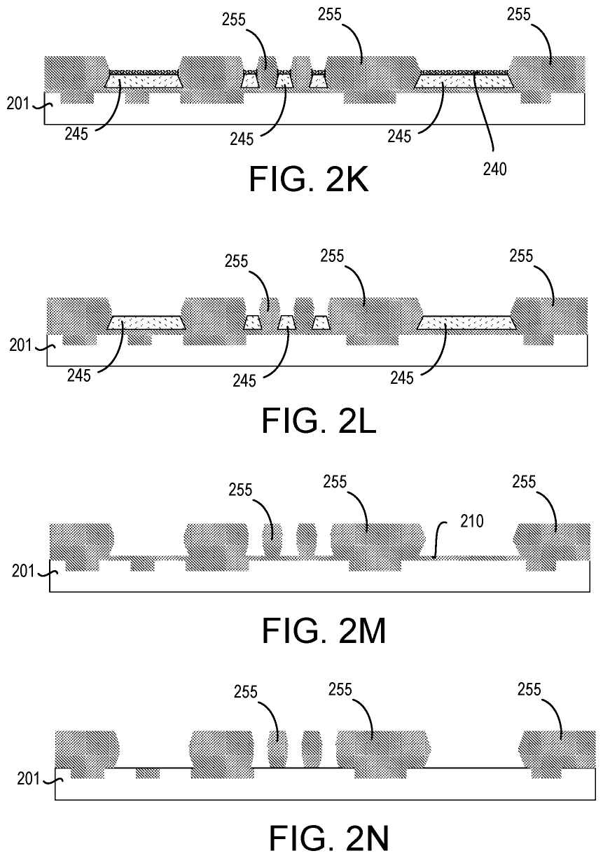

FIG. 1 is a flow diagram illustrating methods 101 for double patterning build-up metallization features, in accordance with some embodiments. FIG. 2A-20 illustrate cross-sectional views of a package metallization build-up as selected operations in the methods 101 are practiced, in accordance with some exemplary embodiments.

Referring first to FIG. 1, methods 101 begin at block 110 with the receipt of a workpiece. In some exemplary embodiments, the workpiece is a contiguous wafer substrate comprising many IC chips. In some other exemplary embodiments, the workpiece is another large format substrate from which IC package preforms may be singulated. Exemplary IC package preforms include package substrates and interposers to which one or more IC chips may be interconnected. In another exemplary embodiment, the workpiece is panelized and includes a plurality of substrates arrayed over the panel in any manner suitable for parallel package assembly. The individual substrates may be, for example, separate IC chips that have been fabricated upstream of block 110, and reconstituted into the panel according to any IC chip reconstitution process, for example. Alternatively, the individual substrates may be separate IC package preforms, each supported within the panelized format.

An exemplary portion of a workpiece is further illustrated in FIG. 2A. As shown, workpiece portion 200 includes a metal seed material 210 over a dielectric material 201. Seed material 210 may have any composition suitable as a seed for the plating of a metallization level. In some embodiments, seed material 210 comprises copper. Seed material 210 may have other compositions, including one or more of gold, silver, cobalt, ruthenium, tungsten, or titanium, for example. Seed material 210 may have any thickness suitable for a subsequent plating process. Dielectric material 201 may have any composition suitable as an electrical insulator for an IC package assembly and/or IC chip. In some embodiments, dielectric material 201 comprises at least one of epoxy, liquid crystalline polymer, or polyimide.

One or more metallization features 205 may also be embedded within dielectric material 201. Metallization features 205 are conductive and may be any of a lateral trace, a vertical via, or surface pad, for example. In some embodiments, metallization features 205 are plated or formed by other deposition techniques such as, but not limited to, electroless deposition, vacuum evaporation, sputtering, chemical vapor deposition, etc. In some embodiments, metallization features 205 comprise at least one of copper, gold, silver, cobalt, graphene, polysilicon or tungsten.

In some embodiments, workpiece portion 200 is formed by build-up methods including a build-up of dry film laminates, for example comprising dielectric material 201. Although only one is illustrated, any number of dielectric material layers and metallization levels may be present over a support (not depicted) as the build-up structure. For cored embodiments, a rigid core is a permanent component of the workpiece. For coreless embodiments, the support is ultimately removed from the laminated stack of the workpiece.

Returning to FIG. 1, methods 101 continue at block 120 where a hybrid plating mask is applied to the workpiece. As noted above, the hybrid plating mask includes multiple layers of photoresist, and the different layers have different photosensitive compositions/chemistries so that they may be separately (successively) patterned through a multiple-patterning process. In exemplary embodiments where the multiple patterning process is a double patterning process, the hybrid plating mask includes two layers of photoresist that have complementary photosensitivity. In one example, a first photoresist layer has positive photosensitivity while a second photoresist layer has negative photosensitivity.

Although the different layers of photoresist in a hybrid plating mask may be in direct contact (e.g., one on top of the other), in some advantageous embodiments, a non-transparent material layer is between the photoresist layers. This non-transparent material layer may be highly reflective or absorptive of the electromagnetic radiation band associated with a photolithography processes employed to image features into the photoresist layers. In some embodiments, a hybrid plating mask includes a non-photosensitive “hard” mask material layer between two photoresist layers. This layer may serve to decouple the imaging of the multiple photosensitive layers, and/or may improve pattern transfer between the multiple photosensitive layers. The hard mask material layer may have any composition that is sufficiently non-transparent (e.g., of sufficiently low transmission to block at least a majority of a target electromagnetic radiation band), such as one or more metals that are reflective, or one or more anti-reflective coatings (ARC) that have high absorption coefficients. The hard mask material layer may advantageously have minimal thickness, and offer good etch selectively relative to the photosensitive materials of a hybrid plating mask.

A hybrid plating mask may be applied according to any techniques suitable for the workpiece. For example, in some advantageous embodiments, dry film resist (DFR) material layers are laminated onto the workpiece to build up the hybrid plating mask using any lamination techniques and materials known to be suitable for the workpiece. As for the photosensitive material layers, the hard mask material layer may also be a dry film laminate, or may be deposited instead by sputtering, CVD, or another low temperature deposition process compatible with the photosensitive material(s). Alternatively, a single multi-layered preformed film stack comprising all material layers of the hybrid plating mask may be applied to the workpiece surface with a single lamination. In still other embodiments, a liquid dispense application technique, such as spray coating (e.g., ultrasonic) or slit coating may be employed for one or more of the resist material layers, and/or any intervening hard mask material layer(s).

In the example further illustrated in FIG. 2B, the formation of a hybrid plating mask includes a first application of a layer of a photosensitive resist material 215 onto seed material 210. Resist material 215, as applied, is in an uncured state. Resist material 215 may have any composition suitable for the imaging apparatus that is to be used. In some embodiments, resist material 215 is an I-line sensitive DFR, although it may instead be sensitive to DUV or EUV bands. In accordance with some embodiments, resist material 215 is a positive photoresist that becomes more soluble in a developer upon exposure to electromagnetic radiation of a suitable wavelength (e.g., I-line). Resist material 215 has a film thickness T1, which may be any thickness providing sufficient imaging resolution. Generally, the resolution possible with a given photoresist declines with increasing resist thickness. In some exemplary embodiments therefore, T1 is below 125 μm (e.g., 5 μm, 10 μm, 15 μm, 25 μm, 80 μm, etc.).

In the example further illustrated in FIG. 2C, hard mask material 220 is next applied over resist material layer 215. In exemplary embodiments, thickness T2 is significantly less than thickness T1 and is advantageously less than 1 μm (e.g., 100-500 nm). In some embodiments where hard mask material 220 is an ARC designed to absorb I-line radiation (e.g., WiDE-15C commercially available from Brewer Science), a thickness T1 of less than 200 nm can absorb ˜80% of incident radiation. Such an ARC may be deposited at the panel level by spray coating, for example. In other embodiments where hard mask material 220 comprises a metal (e.g., copper, titanium, aluminum, gold, or silver), hard mask material 220 may be substantially non-transmissive at a thickness of as little as a few tens of nanometers (e.g., less than 100 nm). Such a metal may be deposited at the panel level by sputter or CVD or electroless plating, for example.

In the example further illustrated in FIG. 2D, photosensitive resist material 225 is applied over hard mask material 220. Resist material 225 is applied in an uncured state. Resist material 225 may have any composition suitable for the imaging apparatus that is to be used. In some embodiments, resist material 225 is also an I-line sensitive DFR, although it may instead be sensitive to DUV or EUV bands. In accordance with some embodiments, resist material 225 is a negative photoresist that becomes less soluble in a developer (e.g., hardened) upon exposure to electromagnetic radiation of a suitable wavelength (e.g., I-line). Resist material 225 has a film thickness T3, which may be any thickness providing sufficient imaging resolution. In some exemplary embodiments, thickness T3 is approximately equal to thickness T1. Approximate equality in thicknesses T1 and T3 may be optimal where response curves for both resist materials 215 and 225 are substantially the same and optimal resolution may be achieved at a thickness that is nearly the same for each. However, thicknesses T1 and T3 may vary as needed for both films to be capable of some target resolution. In some such embodiments, T3 is less than 125 μm (e.g., 5 μm, 10 μm, 15 μm, 25 μm, 80 μm, 120 μm etc.). Therefore, in the illustrated example, hybrid plating mask 227 has a total thickness T4 that is the sum of thickness T1, T2 and T3, which in some thick resist embodiments is over 150 μm, or over 200 μm, and may be 250 μm, or more. In some thin resist embodiments, T4 is between 10 μm and 30 μm, for example.

Returning to FIG. 1 with the hybrid plating mask applied to the workpiece, methods 101 continue at block 130 where a metallization pattern is exposed into a first (topmost) resist layer of the hybrid plating mask. Following any develop process suitable for that resist formulation, the metallization pattern is printed within an upper portion of the hybrid plating mask, for example down to an intervening hard mask layer. For embodiments where a hard mask layer is present, exposure dosing at block 130 may be optimized independently of the other portions of the hybrid plating mask. The develop process may similarly be optimized independently of the other portions of the hybrid mask. In exemplary embodiments, mask features (e.g., pillars or lines) having an aspect ratio of at least 2:1 (height:transverse width) are defined in the first resist layer. In advantageous embodiments, the mask features defined at block 130 have an aspect ratio of at least 3:1, advantageously at least 4:1, and may be 5:1, or more.

In the example further illustrated in FIG. 2E, light of wavelength λ is projected through a reticle 230 having a desired feature pattern. The projected light is cast upon resist material 225, forming an exposure pattern comprising exposed features 235. Being a negative resist formulation, exposed features 235 become cured. As noted above, in the presence of hard mask material 220, the light of wavelength λ does not significantly transmit into resist material 215. In alternative embodiments where a hybrid plating mask lacks hard mask material 220, light dosage may be adjusted to expose only down through thickness T3. Negative resist formulations are generally more photosensitive, requiring lower doses (e.g., ˜50-200 mJ), than positive resist formulations (e.g., ˜1000 mJ). For this reason, a light-blocking hard mask material may be absent from a hybrid plating mask where careful control of the exposure energy is possible. Nevertheless, embodiments including a hard mask material can be expected to be more robust than those lacking the hard mask material.

FIG. 2F further illustrates the structure of FIG. 2E following a develop of resist material 225. In the presence of hard mask material 220, the develop process will expose the hard mask material 220, which may or may not also be soluble in the developer. In exemplary embodiments, wherein the imaging and develop process defines cured mask features 235 having a 2:1 aspect ratio and the thickness T3 is 80 μm, for example, a minimum transverse (lateral) feature size CD₁ of 40 μm may be printed. In advantageous embodiments, where the imaging process defines cured mask features 235 having a 4:1 aspect ratio and the thickness T3 is 80 μm, for example, a minimum transverse feature size CD₁ of 20 μm may be printed. In thin resist embodiments, where the imaging process defines cured mask features 235 having a 4:1 aspect ratio and the thickness T3 is 5-15 μm, for example, a minimum transverse feature size CD₁ of 1.25-3.75 μm may be printed.

The photocuring process may have a characteristic feature sidewall profile, and the example of FIG. 2F illustrates the cured mask features 235 to each have a negatively sloped (i.e. re-entrant) sidewall 236. Sidewall slope may be, for example, between 5 and 30 degrees from normal to a plane of the workpiece. The sidewall slope may also be substantially constant (e.g., to within a few degrees) over the entire thickness T3. Although other feature profiles are possible, for example as a result of dosing and photoresist composition, the illustrated negatively sloped mask feature sidewall 236 may be advantageously achieved in most negative photoresist materials when exposure is with a top-side projection source.

Returning to FIG. 1, methods 101 continue at block 140 where the hard mask material is removed where it is unprotected by an overlying cured mask feature. Removal of the hard mask material may be by any means suitable for the hard mask composition. FIG. 2G further illustrates an example where hard mask material 220 has been etched into mask features 240. In some exemplary embodiments, where hard mask material 220 is an ARC, a positive photoresist developer (e.g., dilute TMAH) may be employed to develop out the ARC with good fidelity to the overlying cured mask feature sidewall. In other embodiments, where the hard mask material 220 is a metal, a chemical etchant suitable for the metal (e.g., HCl for Cu, or KOH for Ti or Al, etc.) may be employed. Being of limited thickness (e.g., <1 μm) undercut of cured mask feature 235 may be limited to little more than 1-2 μm for a fully isotropic removal with some overetch margin.

Returning to FIG. 1, methods 101 continue at block 150 where the pattern defined in a portion of the hybrid mask thus far is transferred into the remainder of the mask. For two layer embodiments, the pattern defined in the upper resist layer is transferred into the lower resist layer, for example with a second exposure and develop. In advantageous embodiments, the second exposure is merely a flood exposure such that no projection reticle alignment is required between blocks 130 and 150. For embodiments where the hybrid plating mask includes a light-blocking hard mask layer, the hard mask layer may further function as a contact mask. For embodiments where the hybrid plating mask lacks a light-blocking hard mask layer, cured mask features need sufficiently low light transmission to facilitate a transfer of their pattern into the lower resist layer.

In the example further illustrated in FIG. 2H, a flood exposure 238 exposes resist material 215, forming unexposed features 245 and exposed regions 246. In exemplary embodiments, where the resist material 215 is a positive resist, exposed regions 246 become more soluble in a developer than unexposed features 245. As further depicted in FIG. 2I, following a suitable develop process that selectively dissolves exposed regions 246, hybrid mask features 250 become fully defined.

The positive resist develop process exposes seed material 210. Cured resist features 235 are similarly resistant to the positive resist develop process. In exemplary embodiments, wherein the imaging and develop process defines unexposed mask features 245 having a 2:1 aspect ratio and the thickness T1 is 80 μm, for example, a minimum transverse feature size CD₁ of 40 μm may again be printed. In advantageous embodiments, where the imaging process defines unexposed mask features 245 having a 4:1 aspect ratio and the thickness T1 is 80 μm, for example, a minimum transverse feature size CD₁ of 20 μm may again be printed. Collectively, therefore, hybrid mask features 250 may have a minimum transverse feature size CD₁ of around 20 μm and a thickness T4 over 160 μm, for example, which amounts to an aspect ratio of 8:1. For less aggressive feature scaling, for example where each of features 235 and 245 have aspect ratios of 3:1, hybrid mask features 250 may have an aspect ratio of 6:1. Such high aspect ratios would be very difficult to achieve in a homogenous plating mask. Of course, where smaller lateral dimensions are desired, thickness T1 may be reduced to 10-30 μm, for example, with the minimum transverse features size CD₁ then being in the range of 1.5 μm-6 μm.

The photo-dissolution process may again have a characteristic feature sidewall profile, which can be expected to be distinct from that of a photocuring process. In the example of FIG. 2I, the unexposed mask features 245 each have a positively sloped sidewall 256. The sidewall slope is therefore complementary to that of cured mask features 235. Sidewall 256 may also have a slope, for example, anywhere between 5 and 30 degrees from normal to a plane of the workpiece. The sidewall slope may again be substantially constant (e.g., to within a few degrees) over the entire thickness T1. Although other feature profiles are possible, for example as a result of dosing and photoresist composition, the illustrated positively sloped mask feature sidewall 256 may be advantageously achieved in most positive photoresist materials when exposure is with a top-side projection source. As this positive slope is complementary to the negative sloped mask feature sidewall 236, the two slopes intersect each other proximal some discontinuity within thickness T4, thereby reducing lateral CD blowout from some targeted CD₁. CD variation over a thickness of hybrid mask features 250 may therefore be significantly less than what would occur in a plating mask of comparable thickness but of a homogenous composition resulting in a fixed slope that is only positive or only negative.

Returning to FIG. 1, with the hybrid plating mask features formed methods 101 continue at block 160 where metal is plated onto portions of the seed material that are left unprotected by the hybrid mask features. Metal plating may be according to any techniques known to be suitable for build-up metallization. In some exemplary embodiments, an electrolytic plating process is employed, for example to deposit a metal comprising copper (e.g., an alloy of predominantly copper). Electroless or other catalyzed selective metal deposition processes may also be possible. In the example illustrated in FIG. 2J, metallization 255 has been plated up from seed material 210. The plating process may be performed for some predetermined duration to reach a metallization thickness, or feature height, that is substantially equal to a height of hybrid mask features 250. For example, metallization 255 may have a thickness T4 that is over 150 μm, potentially over 200 μm, and may be 250 μm, or more. For smaller geometry embodiments, metallization 255 may have a thickness T4 that is only 10-30 μm, for example.

Returning to FIG. 1, methods 101 continue at block 170 where the hybrid plating mask is stripped and any underlying plating seed material removed to separate the plated metallization into metallization features. Any number of mask stripping processes may be employed to successively remove discrete layers of the hybrid mask (e.g., top-down) on a basis of their distinct compositions. In exemplary embodiments illustrated in FIG. 2K, cured mask features 235 are removed with a suitable negative resist strip chemistry, thereby exposing hard mask features 240. As shown in FIG. 2L, hard mask features 240 are then removed with a suitable hard mask etchant (e.g., the same chemistry previously employed to pattern the hard mask material), thereby exposing unexposed mask feature 245. As further shown in FIG. 2M, unexposed mask features 245 are then removed with a suitable positive resist strip chemistry, thereby exposing seed material 210. With the hybrid plating mask removed, exposed portions of seed material 210 may be removed, for example with a flash etch of sufficient duration to clear the seed material thickness but insufficient to significant impact metallization 255. In some exemplary embodiments where seed material 210 comprises predominantly copper, an HCl dip may be performed to arrive at isolated features of metallization 255.

Returning to FIG. 1, methods 101 continue at block 180 where a dielectric material is built up over the metallization features (if desired). Any suitable dielectric material may be deposited with any suitable dry or wet application process. In the example illustrated by FIG. 20, structure 200 is completed with the application of dielectric material 275, which may have any suitable composition, such as any of those described for dielectric material 201.

Completing discussion of FIG. 1, methods 101 may end with the plating of one or more additional metallization levels (if desired) at block 190. In some embodiments, block 190 entails another iteration through blocks 120-180 to form another high-aspect ratio metallization level. In other embodiments, block 190 entails a metallization plating process masked by a single resist material layer (e.g., a low aspect ratio feature plating process).

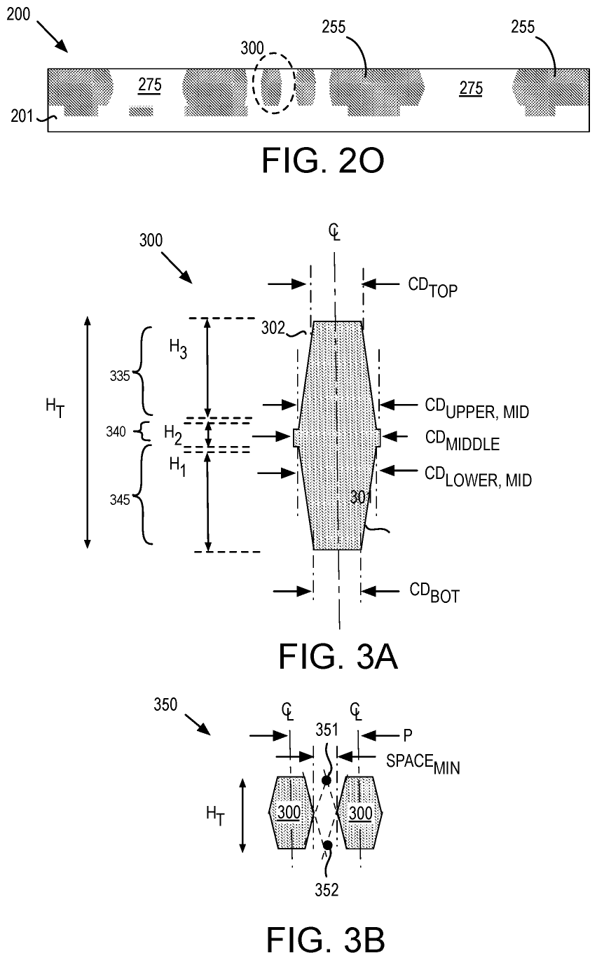

FIG. 3A illustrates an expanded cross-sectional view of a double-patterned build-up metallization feature 300 highlighted in FIG. 2O by dashed line, in accordance with some embodiments. Metallization feature 300 is one feature plated through a hybrid mask having one or more of the attributes described herein. As such, metallization feature 300 has a profile that is complementary to, or a negative of, the hybrid mask feature pattern. Various structural attributes of metallization feature 300 are illustrated in FIG. 3A. One or more of these structural attributes are indicative of the process employed to fabricate metallization feature 300, and/or are advantageous for conveying signals within a IC chip package. Metallization feature 300 has a height H_{T} that is a sum of a height H₁ of a lower feature portion 345, a height H₃ of an upper feature portion 335, and a height H₂ of a middle feature portion 340. In exemplary embodiments, height H_{T} is over 150 μm, or over 200 μm, or over 250 μm, or more. The heights H₁ and H₃ are indicative of the thicknesses of two resist material layers of a hybrid plating mask, and therefore may vary from being nearly equal (e.g., each nearly ½ H_{T}) to one of H₁ and H₃ being a significantly larger fraction of height H_{T} than the other.

Height H₂ is indicative of a hybrid plating mask that included an intervening hard mask layer, with height H₂ being approximately equal to the thickness of that hard mask layer. In exemplary embodiments, height H₂ is less than 10% of height H_{T}, and may be 5%, or less. With height H₂ accounting for little of height H_{T}, and noting that a hybrid mask in accordance with some embodiments need not even include a hard mask layer, middle portion 340 may be absent from a plated metallization feature. Where middle portion 340 is present, a lateral dimension of middle portion 340 may be significantly larger than the largest lateral dimension of upper portion 335 or lower portion 345 as a result of hard mask undercut during the plating mask patterning.

Lower portion 345 and upper portion 335 each have profiles that are distinct and indicative of feature 300 having been plated through a hybrid mask comprising multiple layers of resist material. In the exemplary embodiment illustrated, lower portion 345 and upper portion 335 impart feature 300 with a discontinuous cross-sectional profile that includes an abrupt change in slidewall slope between upper and lower portions 335, 345. In the example illustrated feature 300 has a hexagonal cross-sectional profile (neglecting middle portion 340). Two surfaces of the hexagonal profile are the top and bottom of feature 300, with the remaining surfaces being sidewalls 301 and 302. Sidewall 301 has a sidewall slope complementary to that of sidewall 302. In the illustrated example, sidewall 301 has negative (i.e., re-entrant) slope, which is indicative of lower portion 345 having been plated through a positive photoresist material layer. Sidewall 302 has positive slope, which is indicative of upper portion 335 having been plated through a negative photoresist material layer.

As shown, plated metallization feature 300 has a bottom transverse (lateral) dimension CD_{BOT}, which increases to CD_{LOWER,MID} as a result of the negative slope of sidewall 301. In this example where middle portion 340 is present, CD_{MIDDLE} is slightly larger than CD_{LOWER,MID} indicative of an undercut of a hard mask layer within the hybrid plating mask. Within upper portion 335, the transverse feature dimension decreases from CD_{UPPER, MID} to top lateral dimension of CD_{TOP}. It can be see therefore that the complementary sidewall slopes of upper and lower portions 335, 345 have the advantage of more closely matching CD_{TOP} to CD_{BOT} such that lateral dimension variation over height H_{T} is reduced relative to a feature that was lacking upper and lower portions of complementary sidewall slope.

Notably, there is only one centerline of feature 300 illustrated in FIG. 3A, which is maintained through both lower portion 345 and upper portion 335. As such, lower portion 345 is perfectly aligned with upper portion 335, which is indicative of perfect overlay between multiple resist layers of plating mask. Such perfect overlay is indicative of one of lower portion 345 and upper portion 335 having been self-aligned to the other. This perfect alignment is therefore both an indication a hybrid plating mask in accordance with embodiments herein has been employed to fabricate metallization feature 300, and imparts feature 300 with superior lateral dimension control that helps to achieve a high aspect ratio.

FIG. 3B illustrates cross-sectional view of two adjacent a double-patterned build-up metallization features 350, in accordance with some embodiments. Individual ones of features 350 are substantially identical to feature 300 (FIG. 3A). As shown in FIG. 3B, with each metallization feature having a single centerline, some minimum feature pitch P between the adjacent features may achieve a minimum space SPACE_{MIN} that is limited by the transverse dimension of each feature at approximately a middle point of feature height H_{T}. As a reference, pitch includes a 1:1 line:space ratio. As further illustrated by the dashed lines extending the sidewall slopes of the upper and lower portions of each feature, if both features instead had a monotonically increasing lateral dimension over their height H_{T} it can be seen that an electrical short would occur at SPACE_{MIN}, either between a top of the features at intersection point 351, or between a bottom of the features at intersection point 351. Hence, absent the compound (e.g., hexagonal) feature profile associated with the differing layers of a hybrid plating mask, minimum feature pitch P would need to be greater to ensure no electrical shorts between adjacent features.

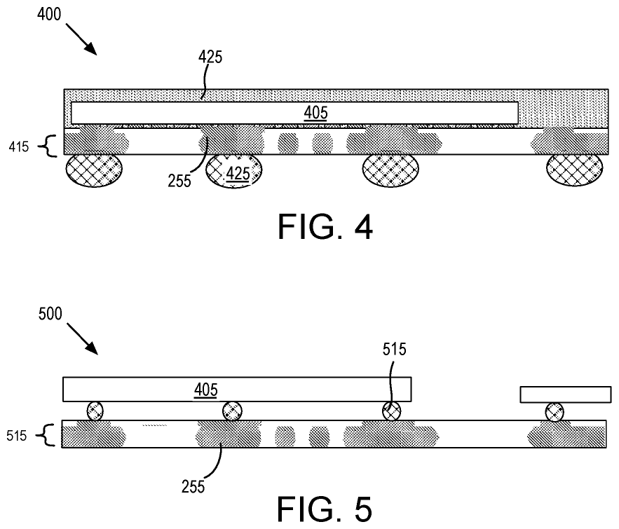

The hybrid plating mask techniques and associated plated metallization features described above may be implemented in a wide variety of IC package components. FIG. 4, for example, illustrates a cross-sectional view of an IC package assembly 400 with a package redistribution level (RDL) 415 that includes build-up metallization 255 that has been plated through a double-patterned hybrid plating mask in accordance with some embodiments. As shown, assembly 400 includes an IC chip (die) 405, embedded within a package material 425. IC die 405 may include one or more integrated circuits. In some embodiments, IC die 405 includes power management circuitry (a PMIC), radio frequency communication circuitry (RFIC), microprocessor circuitry (e.g., application processors, central processors, graphics processors), or memory circuitry (e.g., DRAM, MRAM, RRAM, etc.). In some further embodiments, IC die 405 includes System on a Chip (SoC) circuitry that may further integrate two or more of the above circuitries. Although the illustrated example shows only one IC die 405, which is typical for small form factor packaging embodiments, it is noted that embodiments of the invention may also be applicable to multi-die packages. Package material 425 is advantageously a dielectric. In some exemplary embodiments, package material 425 comprises a cured resin or polymer comprising epoxy and/or silicone, or any other thermoset material known to be suitable for IC die packaging applications.

RDL 415 is plated upon interconnect surfaces (e.g., copper pillars or pads) of IC die 405. RDL 415 comprises metallized redistribution or fan out layers that further couple I/Os and power rails of IC 405 to package interconnects that are, for example, suitable for surface mounting package assembly 400 to a system-level component, such as a printed circuit board (not depicted). In the illustrated example, RDL 415 is electrically coupled to solder interconnect features 425. In some embodiments, the manufacture of RDL 415 includes double-patterning of multiple resist layers of a hybrid plating mask and thin film plating through that hybrid mask. One or more layers of RDL 415 comprises metallization 255 plated with a hybrid plating mask, for example as described elsewhere herein, and having one or more of the attributes described herein, for example as described elsewhere herein. One or more dry film dielectric build up techniques may also be employed, such as, but not limited to the lamination of resinous films (e.g., GX-series films commercially available from Ajinomoto Fine-Techno Co., Inc.).

FIG. 5 illustrates a cross-sectional view of a package assembly 500 including IC 405 interconnected by solder features 515 to a package substrate 515 including a high aspect-ratio build-up metallization 255, in accordance with some embodiments. As shown, package substrate 515 includes comprises metallization 255 that has been plated with a hybrid plating mask, for example as described elsewhere herein, and having one or more of the attributes described herein, for example as described elsewhere herein.

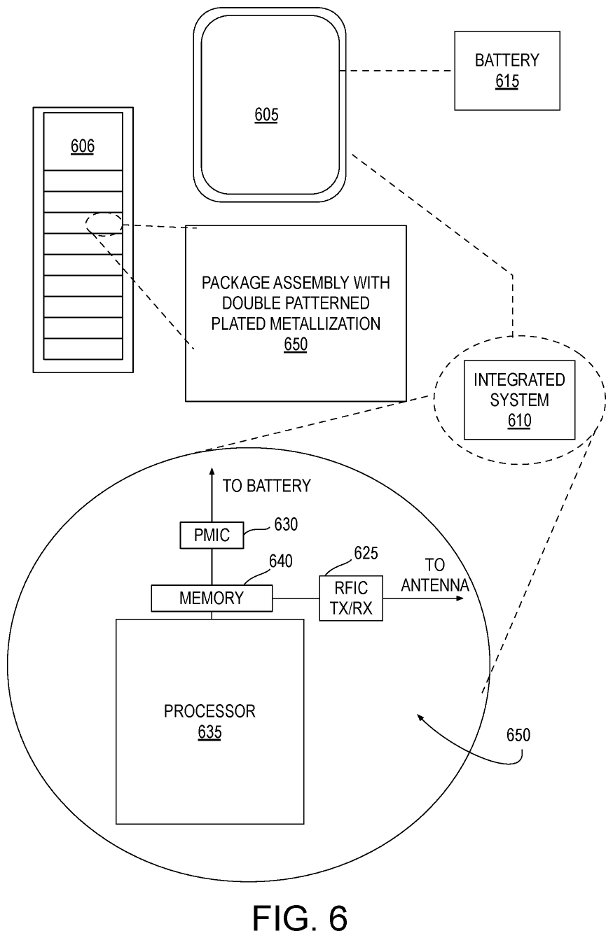

FIG. 6 illustrates a mobile computing platform and a data server machine employing a package assembly including double-patterned metallization features, for example as described elsewhere herein. The server machine 606 may be any commercial server, for example including any number of high-performance computing platforms disposed within a rack and networked together for electronic data processing, which in the exemplary embodiment includes a packaged monolithic SoC. The mobile computing platform 605 may be any portable device configured for each of electronic data display, electronic data processing, wireless electronic data transmission, or the like. For example, the mobile computing platform 605 may be any of a tablet, a smart phone, laptop computer, etc., and may include a display screen (e.g., a capacitive, inductive, resistive, or optical touchscreen), a chip-level or package-level integrated system 610, and a battery 615.

As a system component within the server machine 606, package assembly 650 may include a memory block (e.g., RAM) and a processor block (e.g., a microprocessor, a multi-core microprocessor, baseband processor, or the like) interconnected through metallization features that have been plated through a hybrid mask, for example as described elsewhere herein and/or have a double-patterned feature structure, for example as described elsewhere herein. Assembly 650 includes one or more of a power management integrated circuit (PMIC) 630, RF (wireless) integrated circuit (RFIC) 625 including a wideband RF (wireless) transmitter and/or receiver (TX/RX), and memory 635 are interconnected double-patterned metallization features, which may be further interconnect onto a board within either server 606 or mobile device 605.

Functionally, PMIC 630 may perform battery power regulation, DC-to-DC conversion, etc., and so has an input coupled to battery 615 and with an output providing a current supply to other functional modules. As further illustrated, in the exemplary embodiment, RFIC 625 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

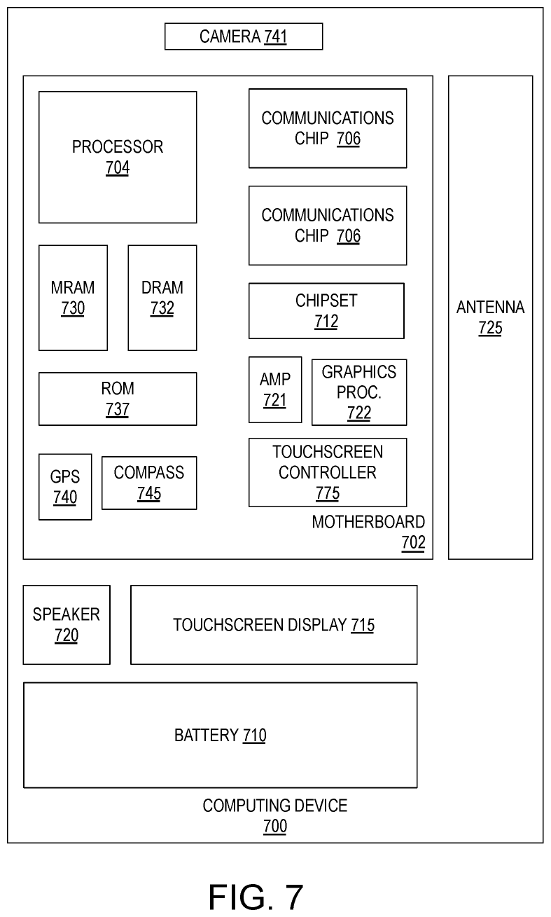

FIG. 7 is a functional block diagram of an electronic computing device, in accordance with some embodiments. Computing device 700 may be found inside platform 605 or server machine 606, for example. Device 700 further includes a motherboard 702 hosting a number of components, such as, but not limited to, a processor 704 (e.g., an applications processor), which may be in a package coupled to motherboard 702 by a high-aspect metallization features, for example having any of the attributes described elsewhere herein. Processor 704 may be physically and/or electrically coupled to motherboard 702. In some examples, processor 704 includes an integrated circuit die packaged within the processor 704 and connections between the IC die and the processor 704 are interconnected through high aspect ratio metallization features, for example having any of the attributes described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 706 may also be physically and/or electrically coupled to processor 704. Depending on its applications, computing device 700 may include other components that may or may not be physically and electrically coupled to motherboard 702. These other components include, but are not limited to, volatile memory (e.g., DRAM), non-volatile memory (e.g., ROM), flash memory, a graphics processor, a digital signal processor, a crypto processor, a chipset, an antenna, touchscreen display, touchscreen controller, battery, audio codec, video codec, power amplifier, global positioning system (GPS) device, compass, accelerometer, gyroscope, speaker, camera, and mass storage device (such as hard disk drive, solid-state drive (SSD), compact disk (CD), digital versatile disk (DVD), and so forth), or the like. Any of these other components may also be coupled to motherboard 702, for example double-patterned plated metallization features, for example having any of the attributes described elsewhere herein.

Communication chips 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 706 may implement any of a number of wireless standards or protocols, including but not limited to those described elsewhere herein. As discussed, computing device 700 may include a plurality of communication chips 706. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In first example, a microelectronic device package assembly comprises a chip comprising an integrated circuit (IC), a package material adjacent to an active side of the chip, and a metallization feature electrically coupled to the chip. The metallization feature has a height extending through at least a partial thickness of the package material. The metallization feature comprises a sidewall with a discontinuity between a first portion having a first sidewall slope, and a second portion having a second sidewall slope.

In second examples, for any of the first examples the first portion has a positive sidewall slope, and a second portion has a negative sidewall slope.

In third examples, for any of the first through second examples the metallization feature has a single centerline over the height, the single centerline passing through a center of a transverse width of the first portion and a center of a transverse width of the second portion.

In fourth examples, for any of the first through third examples the metallization feature has an aspect ratio in which the height of the metallization feature is at least six times larger than a largest transverse width of the metallization feature.

In fifth examples, for any of the first through fourth examples, the metallization feature has an aspect ratio in which the height of the metallization feature is at least eight times larger than the largest transverse width of the metallization feature.

In sixth examples, for any of the first through fifth examples a height of the first portion is substantially equal to a height of the second portion.

In seventh examples, for any of the first through sixth examples, the metallization feature has a hexagonal cross-section with the positive sidewall slope intersecting the negative sidewall slope.

In eighth examples, for any of the second through seventh examples the positive sidewall slope is between 60 and 85° from a plane of the package assembly, and wherein the negative sidewall slope is between 60 and 85° from the plane of the package assembly.

In ninth examples, for any of the first through eighth examples the metallization feature comprises a third portion between the first and second portions, the third portion having a height that is no more than 10% of the height of the metallization feature.

In tenth examples, for any of the first through ninth examples the metallization feature comprises a third portion between the first and second portions, the third portion having a lateral dimension that is larger than a largest lateral dimension of the first or second portions.

In eleventh examples, the metallization feature comprises copper.

In twelfth examples, a packaged microelectronic device comprises an integrated circuit (IC) chip, wherein a first side of the IC chip is electrically coupled to one or more redistribution layers of a package, and a package substrate electrically coupled to the microprocessor chip through the redistribution layers. At least one the package substrate and the redistribution layers further comprises a metallization feature having a height extending through at least a partial thickness of a dielectric material, wherein the metallization feature comprises a first portion having a positive sidewall slope, and a second portion having a negative sidewall slope.

In thirteenth examples, for any of the twelfth examples, the metallization feature has an aspect ratio in which the height of the metallization feature is at least six times larger than a largest transverse width of the metallization feature.

In fourteenth examples, a method of fabricating a microelectronic package component comprises receiving a workpiece, the workpiece comprising a seed material over a dielectric material. The method comprises applying a hybrid mask stack over the seed material, and the hybrid mask includes at least a negative resist material layer and a positive resist material layer. The method comprises photolithographically defining a feature pattern into the negative resist material layer. The method comprises exposing a first region of the seed material by photolithographically transferring the feature pattern into the positive resist material layer. The method comprises plating metallization over the first region of the seed material. The method comprises stripping the hybrid mask stack to expose a second region of the seed material, and defining metallization features by removing the second region of the seed material.

In fifteenth examples, for any of the fourteenth examples the workpiece comprises an integrated circuit (IC) die, or IC package substrate

In sixteenth examples, for any of the fourteenth through fifteenth examples applying the hybrid mask stack further comprises at least one dry film lamination.

In seventeenth examples, for any of the fourteenth through sixteenth examples the hybrid mask stack further comprises a non-photosensitive hard mask material between the negative resist material layer and the positive resist material layer.

In eighteenth examples, for any of the fourteenth through seventeenth examples the hard mask material blocks a majority of light employed in photolithographically defining the feature pattern into the negative resist material layer.

In nineteenth examples, for any of the fourteenth through eighteenth examples transferring the feature pattern photolithographically into the positive resist material layer further comprises a flood exposure of the positive resist material.

In twentieth examples, for any of the fourteenth through nineteenth examples the hybrid mask stack has a total thickness of at least 30 μm.

It will be recognized that principles of the disclosure are not limited to the embodiments so described, but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A microelectronic device package assembly, comprising:
a chip comprising an integrated circuit (IC);
a package material adjacent to an active side of the chip; and
a metallization feature electrically coupled to the chip, the metallization feature having a height extending through at least a partial thickness of the package material, wherein the metallization feature comprises a sidewall with a discontinuity between a first portion having a first sidewall slope, and a second portion having a second sidewall slope.

2. The package assembly of claim 1, wherein the first portion has a positive sidewall slope, and a second portion has a negative sidewall slope.

3. The package assembly of claim 1, wherein the metallization feature has a single centerline over the height, the single centerline passing through a center of a transverse width of the first portion and a center of a transverse width of the second portion.

4. The package assembly of claim 1, wherein the metallization feature has an aspect ratio in which the height of the metallization feature is at least six times larger than a largest transverse width of the metallization feature.

5. The package assembly of claim 4, wherein the metallization feature has an aspect ratio in which the height of the metallization feature is at least eight times larger than the largest transverse width of the metallization feature.

6. The package assembly of claim 4, wherein a height of the first portion is substantially equal to a height of the second portion.

7. The package assembly of claim 1, wherein the metallization feature has a hexagonal cross-section with the positive sidewall slope intersecting the negative sidewall slope.

8. The package assembly of claim 2, wherein the positive sidewall slope is between 60 and 85° from a plane of the package assembly, and wherein the negative sidewall slope is between 60 and 85° from the plane of the package assembly.

9. The package assembly of claim 1, wherein the metallization feature comprises a third portion between the first and second portions, the third portion having a height that is no more than 10% of the height of the metallization feature.

10. The package assembly of claim 1, wherein the metallization feature comprises a third portion between the first and second portions, the third portion having a lateral dimension that is larger than a largest lateral dimension of the first or second portions.

11. The package assembly of claim 1, wherein the metallization feature comprises copper.

12. A packaged microelectronic device, comprising:
an integrated circuit (IC) chip, wherein a first side of the IC chip is electrically coupled to one or more redistribution layers of a package; and
a package substrate electrically coupled to the microprocessor chip through the redistribution layers, wherein at least one the package substrate and the redistribution layers further comprises a metallization feature having a height extending through at least a partial thickness of a dielectric material, wherein the metallization feature comprises a first portion having a positive sidewall slope, and a second portion having a negative sidewall slope.

13. The packaged microelectronic device of claim 11, wherein the metallization feature has an aspect ratio in which the height of the metallization feature is at least six times larger than a largest transverse width of the metallization feature.

14. A method of fabricating a microelectronic package component, the method comprising:
receiving a workpiece, the workpiece comprising a seed material over a dielectric material;
applying a hybrid mask stack over the seed material, wherein the hybrid mask includes at least a negative resist material layer and a positive resist material layer;
photolithographically defining a feature pattern into the negative resist material layer;
exposing a first region of the seed material by photolithographically transferring the feature pattern into the positive resist material layer;
plating metallization over the first region of the seed material;
stripping the hybrid mask stack to expose a second region of the seed material; and
removing the second region of the seed material to define metallization features.

15. The method of claim 14, wherein the workpiece comprises an integrated circuit (IC) die, or IC package substrate.

16. The method of claim 14, wherein applying the hybrid mask stack further comprises at least one dry film lamination.

17. The method of claim 14, wherein the hybrid mask stack further comprises a non-photosensitive hard mask material between the negative resist material layer and the positive resist material layer.

18. The method of claim 17, wherein the hard mask material blocks a majority of light employed in photolithographically defining the feature pattern into the negative resist material layer.

19. The method of claim 14, wherein transferring the feature pattern photolithographically into the positive resist material layer further comprises a flood exposure of the positive resist material.

20. The method of claim 14, wherein the hybrid mask stack has a total thickness of at least 30 μm.
